(19) United States
(12) Patent Application Publication
(10) Pub. No.: US 2007/0101220 A1
(43) Pub. Date: May 3, 2007

(54) Systems and methods for accessing input/output devices

(76) Inventor: Masserati H. So, Fremont, CA (US)

Correspondence Address: CARR & FERRELL LLP, 2200 GENG ROAD, PALO ALTO, CA, 94303, US

(21) Appl. No.: 11/588,488

(22) Filed: Oct. 26, 2006

Related U.S. Application Data
(60) Provisional application No. 60/596,873, filed on Oct. 27, 2005.

(51) Int. Cl. G01R 31/28; G06F 9/46

(52) U.S. Cl. 714/724; 719/321

(57) ABSTRACT

Systems and methods are provided for a hardware access tool to access a computer input/output (I/O) device coupled to a standard I/O bus on a host computer system. Upon receiving a standard I/O bus command, the hardware access tool translates the bus command on-the-fly for operation on a selected I/O device. The hardware access tool includes a bootable operating system for use when operating the invention, thus avoiding possible corruption of any existing host operating system. Accessing an input/output device may be for testing, debugging, developing, programming, configuring, or any other reason for accessing an I/O device. The hardware access tool may operate with standard I/O bus architectures such as PCI, CompactPCI, PMC, PCI-X, PCI Express, InfiniBand, HyperTransport, PC CardBus, PCMCIA, AGP, USB, ExpressCard, and IEEE 1394.

### CROSS-REFERENCE TO RELATED APPLICATIONS

The present application claims priority of U.S. Provisional Patent Application Ser. No. 60/596,873 filed on Oct. 27, 2005 for “System and Method for Programming and Testing Hardware Devices Attached to Configurable Computer I/O Bus with Hardware Abstraction Software,” herein incorporated by reference.

### BACKGROUND OF THE INVENTION

1. Field of the Invention

The present invention relates generally to input/output devices, and more particularly to systems and methods for accessing input/output devices.

2. Description of Related Art

Accessing an input/output (I/O) device attached to an I/O bus for testing, debugging or developing typically uses one of several known environments. One known environment requires a secondary communication channel (as opposed to the primary host communication I/O bus) between the I/O device and the host computer system used to access the I/O device. For example, Joint Test Action Group (JTAG) interface uses a secondary communication channel and uses specialized debugging hardware and software to facilitate communication with the I/O device. Also, secondary communication channel environments are restricted to debugging the I/O device itself as opposed to debugging an interface connecting the I/O device and a host bus. For example, the JTAG interface is usually used to program and debug FPGA logic behind a PCI host bridge interface on the I/O device. Some secondary communication channels consist of a non-standard debug port that requires specialized hardware, firmware, and host software applications to exercise the functionality of the I/O device.

A second known environment involves commercially available software tools that provide access to common I/O hardware functionality, namely, configuration, memory access, and interrupt servicing. However, these software tools require the user to manually enter one command at a time to test the functionality of the I/O device. Also, because these software tools are installed and executed in a host operating system environment, unexpected behavior from the I/O device may adversely affect the host bus to render the entire computer system inoperable. Also, unexpected behavior may cause critical portions of the host operating system to be corrupted which may require the user to restart or reinstall the host operating system. Unfortunately, such host operating system corruption is not uncommon or infrequent when testing the functionality of an I/O device using these software tools.

A third known environment involves a custom software tool to test unique features of an I/O device under development. The custom software tool requires a custom software driver to access the I/O device and a custom software application with a unique interface to the custom software driver. While the custom software tool may provide the most tailored solution in testing functionality of the I/O device, development cost may be high. Additionally, the custom software tool may be too specialized to use with later versions of the same I/O device or for use with different I/O buses and/or host operating systems. Furthermore, as described above, custom software tools still possess an inherent risk of corrupting the host operating system, because the custom software tool also runs in the existing host operating system.

What is needed, therefore, is an improved environment for testing, debugging, and development of an I/O device.

### SUMMARY OF THE INVENTION

Systems and methods are provided to permit access to an input/output (I/O) device using standard I/O bus commands. Upon user entry of a standard I/O bus command, standard I/O bus commands are translated on-the-fly for operation on a selected I/O device attached to the standard I/O bus. A bootable non-host operating system is included for use during operation, thus avoiding possible corruption of any existing host operating system. Also, a scan is performed to determine I/O devices coupled to internal and external standard I/O buses and to determine I/O device configuration. Optionally, the user is provided with the ability to create and save scripts made up of one or more standard I/O bus commands and one or more programmatic commands. These scripts are useful for more thorough and/or repetitive accessing of the I/O device. Further, the scripts are compatible with later versions of the standard I/O bus, because the scripts use translation software written for standard I/O bus commands. Optionally, the user may enter the standard I/O bus commands via a graphical user interface module. Also, the scripts are reusable across different versions or updates of the I/O bus, across different applications, and across different operating systems.

Various embodiments include a method for accessing an I/O device by running a non-host operating system on a host computer system, the non-host operating system being separate from a host operating system. The method receives a user-specified standard I/O bus command and then translates the user-specified standard I/O bus command into a set of low-level instructions. Additionally, the method communicates the set of low-level instructions across a standard I/O bus to the input/output device for execution.

Some embodiments include a computer readable medium having embodied thereon a program, the program being executable by a processor for accessing an I/O device. The program is executable by a processor to run a non-host operating system on a host computer system, the non-host operating system being separate from a host operating system. The program is executable by a processor to receive a user-specified standard I/O bus command and then to translate the user-specified standard I/O bus command into a set of low-level instructions. Additionally, the program is executable by a processor to communicate the set of low-level instructions across a standard I/O bus to the input/output device for execution.

Various embodiments include a system for accessing an I/O device. The system includes a host computer system configured to run a non-host operating system, the non-host operating system being separate from a host operating system. The system also includes a hardware access tool configured to receive a user-specified standard I/O bus command and to translate the user-specified standard I/O bus command into a set of low-level instructions. Also, the hardware access tool is configured to communicate the set of low-level instructions across a standard I/O bus to the I/O device for execution.

### BRIEF DESCRIPTION OF THE DRAWINGS

FIG. 1 is a block diagram illustrating an exemplary input/output device access configuration, according to various embodiments of the invention.

FIG. 2 is a block diagram illustrating an exemplary hardware access tool, according to various embodiments of the invention.

FIG. 3 is a block diagram illustrating an exemplary scripting engine, according to various embodiments of the invention.

FIG. 4 illustrates a method of starting the hardware access tool, according to various embodiments of the invention.

FIG. 5 illustrates a method of using the hardware access tool, according to various embodiments of the invention.

FIG. 6 illustrates a method of translating a standard I/O bus command into the set of low-level instructions of FIG. 5, step 530, according to various embodiments of the invention.

FIG. 7 illustrates a screenshot of a graphical user interface module generating a hardware toolbox and a console window, according to various embodiments of the invention.

FIG. 8 illustrates a screenshot of a graphical user interface module generating a register configuration of an input/output device, according to various embodiments of the invention.

FIG. 9 illustrates a screenshot of a graphical user interface module displaying a script and the test output, according to various embodiments of the invention.

### DETAILED DESCRIPTION

Systems and methods for accessing an input/output (I/O) device using a hardware access tool are disclosed. The hardware access tool runs a non-host operating system on a host computer system, the non-host operating system being separate from a host operating system. The hardware access tool translates one or more user-specified standard I/O bus commands and/or one or more user-specified programmatic commands into a set of low-level instructions. The hardware access tool then communicates the set of low-level instructions across a standard I/O bus to the I/O device for execution.

In various embodiments, the hardware access tool saves a script consisting of two or more user-specified standard I/O bus commands and optionally may include one or more user-specified programmatic commands. The scripts may be executed during a current session, during a later session, under a different software application, and/or under a different operating system.

The hardware access tool has additional capabilities in various embodiments. The hardware access tool can determine the functionality and configuration of the I/O device. The hardware access tool can configure the I/O device and read and write to the I/O device's memory, as well as servicing asynchronous events from the I/O device. The hardware access tool can also provide access to the I/O device via a graphical user interface module.

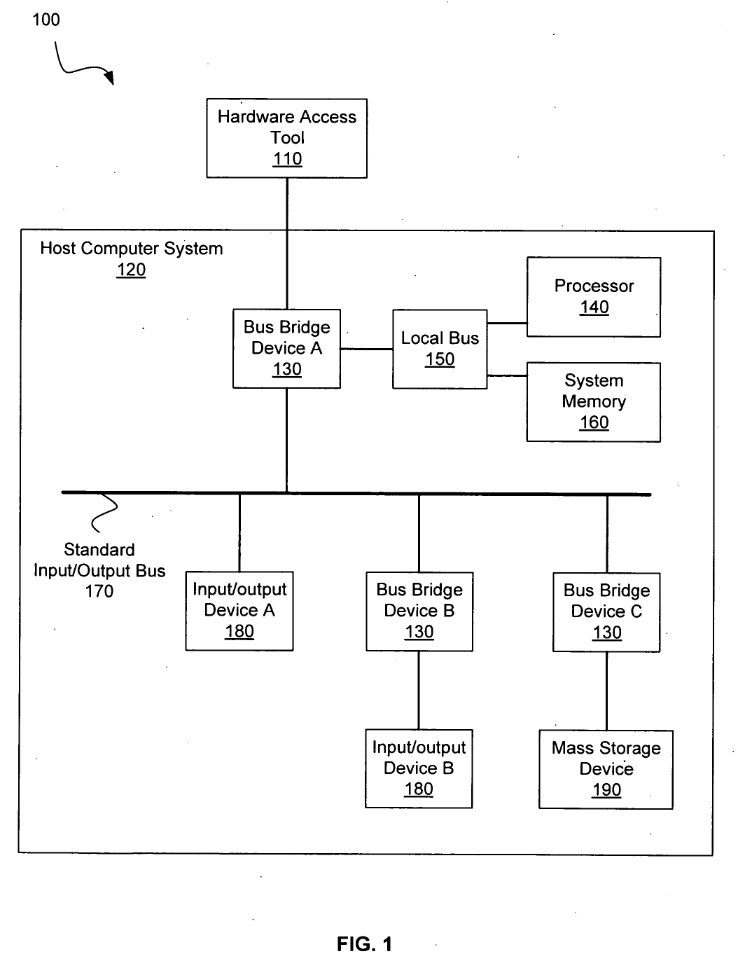

FIG. 1 is a block diagram illustrating an exemplary I/O device access configuration 100, according to various embodiments of the invention. The configuration 100 includes a hardware access tool 110 coupled to a host computer system 120. The host computer system 120 includes bus bridge devices A-C 130, a processor 140, a local bus 150, system memory 160, a standard I/O bus 170, I/O devices A-B 180, and a mass storage device 190.

The hardware access tool 110 is self-contained and does not use a host boot device or services of a host operating system of the host computer system 120. In various embodiments, the hardware access tool 110 may be located in a mass storage device (not depicted) that is coupled to the bus bridge device A 130 via a mass storage bus (not depicted), e.g. IDE, SATA, or SCSI. In some embodiments, the bus bridge device A 130 may be coupled to other mass storage devices of the host computer system 120, such as a hard drive that contains the host boot device.

Mass storage buses employ mass storage bus channels that effectively segregate multiple coupled mass storage devices. Thus, a state of a host boot device and host operating system may be left undisturbed while the hardware access tool 110 is operating, thereby avoiding unexpected events occurring during I/O device access. In various embodiments, the hardware access tool 110 may be located in a mass storage device connected to or inserted into the standard I/O bus 170, either directly or via any of the bus bridge devices A-C 130.

The hardware access tool 110 may access an I/O device, such as I/O device A 180. The hardware access tool 110 is further discussed herein.

Accessing an I/O device may be for testing, debugging, developing, programming, program designing, configuring, automated manufacturing testing or any other reason for accessing an I/O device such as production release validating. The I/O device may be any PCI, PCI-X, PCI Express, AGP, PC CardBus, PCMCIA, CompactPCI, USB, FireWire, or any other configurable standard I/O bus based I/O device. The I/O device may be connected directly to the standard I/O bus 170, such as I/O device A 180, or may be connected to the standard I/O bus 170 via an intermediate bus, such as I/O device B 180 is connected to bus bridge device B 130. The I/O device may also be connected via multiple bus bridge devices A-C 130.

The host computer system 120 is any computer system that communicates with an I/O device. The bus bridge devices A-C 130 may be a PCI-to-PCI bridge, PCI-to-PCI-X bridge, PCI-to-PCI Express bridge, PCI-to-USB bridge, PCI-to-IEEE 1394 bridge, host-to-PCI bridge, or any other bridge device that interconnects the native interface of the I/O device to the standard I/O bus 170 and to the processor 140.

In various embodiments, the processor 140 and system memory 160 are connected to the local bus 150. The local bus 150 is connected to bus bridge device A 130. The bus bridge devices A-C 130 and I/O device A 180 are connected to the standard I/O bus 170. I/O device B 180 and mass storage device 190 are connected to bus bridge device B 130 and bus bridge device C 130, respectively. In various embodiments, the host computer system 120 configuration may vary from system to system. For example, in some embodiments, the processor 140 and/or system memory 160 may be connected to the standard I/O bus 170. In other embodiments, the processor 140 may include several processors. The system memory 160 may include RAM and/or other volatile memory. In some embodiments, the standard I/O bus 170 represents two or more physical standard I/O buses interconnected by bus bridge devices.

The standard I/O bus 170 may be any computer bus that has a standard set of bus commands, such as, PCI, CompactPCI, PMC, PCI-X, PCI Express, InfiniBand, PC CardBus, PCMCIA, USB, IEEE 1394 (FireWire), AGP, 1-Wire, HyperTransport, I²C, ExpressCard, or Serial Peripheral Interface Bus.

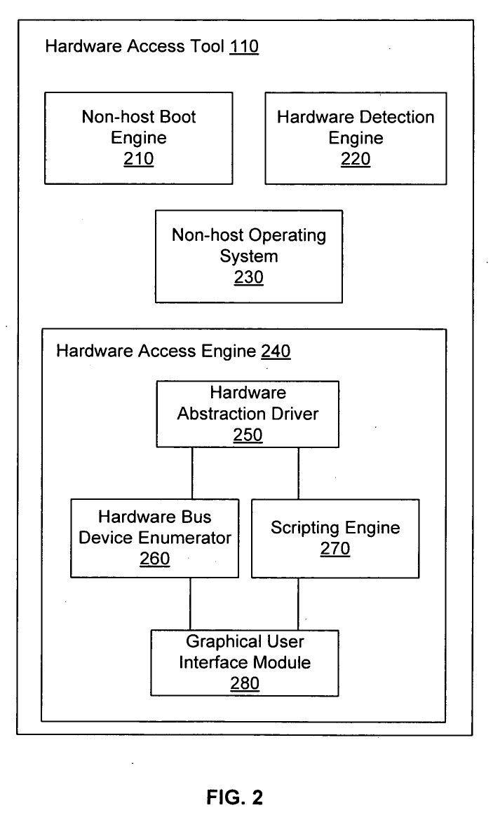

FIG. 2 is a block diagram illustrating an exemplary hardware access tool 110, according to various embodiments of the invention. The hardware access tool 110 contains a non-host boot engine 210, a hardware detection engine 220, a non-host operating system 230, and a hardware access engine 240.

The non-host boot engine 210 initiates the running of the hardware access tool 110. The non-host boot engine 210 is a self-contained booting engine, i.e., the non-host boot engine 210 does not use the services of the host system boot device and does not require additional user intervention. The non-host boot engine 210 may require minimal interaction with the host computer system 120 to be functional, such as using the processor 140 to send instructions across buses to I/O devices.

The hardware detection engine 220 performs a scan of the host computer system 120 to determine I/O devices coupled to the standard I/O bus 170, local bus 150, and bus bridge devices A-C 130. For example, the hardware detection engine 220 may detect one or more processors, system memory, mass storage controllers, video controllers, audio controllers, network controllers, and/or bus controllers. In some embodiments, the hardware detection engine 220 probes the I/O device functionality that is common across various families of a particular I/O device to help in providing access and control for the hardware access tool 110. In various embodiments, the hardware detection engine 220 generates an I/O device list for use by other components of the hardware access tool 110.

The non-host operating system 230 is a self-contained operating system. As both the non-host boot engine 210 and the non-host operating system 230 are self-contained, unintentional changes to the mass storage device 190 are avoided, such as altering a boot sector, deleting code and/or corrupting the host operating system. In some embodiments, the non-host operating system 230 may reside on a bootable media such as a CD, DVD or USB flash drive. The non-host operating system 230 may be based on Knoppix, Windows XP Embedded, Mac OS, MAC OS X, Solaris, BeOS, ReactOS, UNIX, any embedded OS, or any Linux variant that is capable of executing on-the-fly from a CD/DVD/USB/other bootable medium. Some exemplary embodiments are Knoppix live CD, DSL (Damn Small Linux), Adios LiveCD and CentOS 4 Live.

The non-host operating system 230 uses information about the family of the particular I/O device obtained by the hardware detection engine 220 to determine operating system software to load into system memory 160. In various embodiments, the non-host operating system 230 loads certain portions of the binary code into system memory 160 to be executed by the processor 140 and removes unused binary code portions from the system memory 160, thus efficiently using memory. By efficiently using memory, the rest of the hardware access tool 110 may be executed without requiring software installation on a mass storage device of the host computer system 120, such as mass storage device 190. In some embodiments, the non-host operating system 230 executes code instructions on-the-fly.

The hardware access engine 240 may include a hardware abstraction driver 250, a hardware bus device enumerator 260, a scripting engine 270, and a graphical user interface module 280. The hardware abstraction driver 250 determines functionality of the I/O device by performing standard I/O bus 170 specific execution cycles. Also, the hardware abstraction driver 250 relays the functionality to the rest of the hardware access engine 240 components. In various embodiments, the execution cycles include configuration cycles, memory cycles, asynchronous/interrupt cycles, isochronous cycles, control cycles, and/or bulk transfer cycles.

The hardware abstraction driver 250 executes as a privileged software module integrated with the currently executing non-host operating system 230. Thus, the hardware abstraction driver 250 may provide a layer of hardware abstraction for the hardware bus device enumerator 260, the scripting engine 270, and the graphical user interface module 280. The layer of hardware abstraction effectively encapsulates implementation details of how the processor 140 and a supporting chipset manage actual execution cycles. The hardware abstraction driver 250 manages hardware access via a group of primitive low-level commands that invoke applicable execution cycles on the I/O device.

The hardware bus device enumerator 260 is layered above the hardware abstraction driver 250. The hardware bus device enumerator 260 probes standard I/O buses, bus bridge devices, and local buses in the system for attached I/O devices using configuration cycles from the hardware abstraction driver 250. For each I/O device, the hardware bus device enumerator 260 may retrieve configuration information, such as a unique ID, a resource required for the host computer system 120, and/or a type of execution cycle supported by the I/O device.

The scripting engine 270 translates commands written in hardware access language into a set of low-level instructions. The scripting engine 270 is discussed further herein.

Hardware access language may be used to access an I/O device throughout the device's product life cycle, e.g., development, production, commercialization, and maintenance. Hardware access language is a high-level interpretive/compiled language that is streamlined for efficient access to execution cycles available to I/O devices. Some examples of the types of hardware access language commands include variable declarations, variable assignments, common math functions, bitwise operations, looping, conditionals, and code branching, as well as I/O device execution cycles such as memory reads/writes, configuration reads/writes, asynchronous event handling, isochronous transfers, bulk transfers, and other standard I/O bus specific functions.

In various embodiments, hardware access language consists of standard I/O bus commands and programmatic commands. The standard I/O bus command is any command on a standard I/O bus directed to an I/O device. The standard bus I/O command allows native access to the I/O device. For example, some PCI bus standard commands are PCIR (PCI configuration read), PCIW (PCI configuration write), MW (memory write), MR (memory read), IOW (input/output write), IOR (input/output read), HISR (hook ISR), and UISR (unhook ISR). For another example, some USB bus commands allow control, bulk, interrupt, and isochronous read/write cycles. Read commands are like functions in that they return values that can be used in a scripting construct.

The programmatic command is any high-level language command that controls flow and/or behavior of the host computer system 120. In various embodiments, programmatic commands may be the same as or similar to commands of other high-level languages such as Microsoft's VBScript and Sun Microsystems' JavaScript. The scripting engine 270 via the programmatic commands provides the framework for the standard I/O bus commands to be structured and controlled.

The graphical user interface module 280 is optional and provides a user interface. In various embodiments, the graphical user interface module 280 may display a list of the I/O devices obtained by the hardware detection engine 220 and/or configuration information and other detailed information of the I/O devices ascertained by the hardware bus device enumerator 260. In various embodiments, upon selection of an I/O device, the graphical user interface module 280 may display detailed configuration information about the I/O device and/or may allow access I/O device functions. Some commands used to access I/O device functions can include programming binary code for field programmable gate array implementation, reading and writing control registers, and reading and writing memory. In some embodiments, the graphical user interface module 280 displays an effect of the set of low-level instructions of the scripting engine 270, such as the handling of asynchronous events. In other embodiments, the graphical user interface module 280 displays how isochronous and bulk data transfers are handled. The graphical user interface module 280 is discussed further herein.

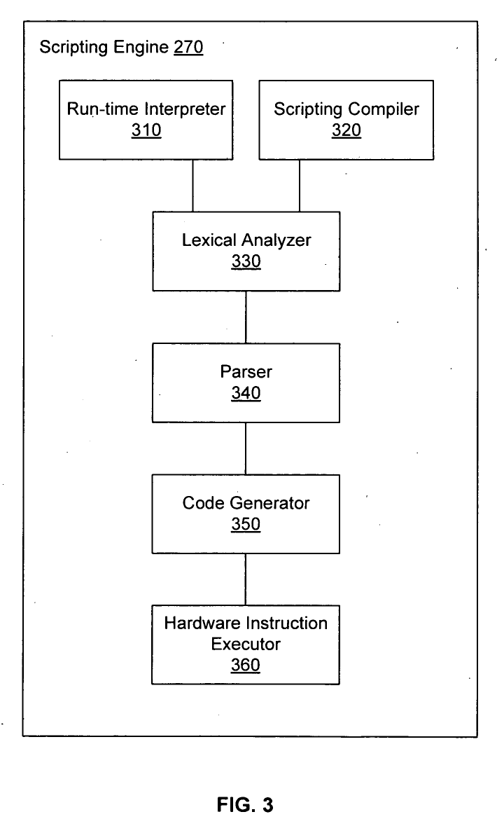

FIG. 3 is a block diagram illustrating an exemplary scripting engine 270, according to various embodiments of the invention. The scripting engine 270 consists of a run-time interpreter 310, a scripting compiler 320, a lexical analyzer 330, a parser 340, a code generator 350, and a hardware instruction executor 360. The run-time interpreter 310 is used during an interactive session when user-specified standard I/O bus commands and user-specified programmatic commands are processed and executed interactively. The scripting compiler 320 is used during a non-interactive offline session (e.g., a session using a text file) when processing and execution are deferred until submitted to the run-time interpreter 310.

The scripting compiler 320 allows a user to create, save and edit scripts. Scripts are like functions or routines in a programming language. Scripts can be stored into a USB key for future use and can be executed from the console window. Also, scripts are reusable across different versions or updates of the I/O bus, across different applications, and across different operating systems. The scripts are reusable because they are based on a standard specification defined for the standard I/O bus. The standard specification does not change when version changes or updates are made to the standard I/O bus.

Both the run-time interpreter 310 and the scripting compiler 320 accept commands written in hardware access language. Both the run-time interpreter 310 and the scripting compiler 320 use the services of the lexical analyzer 330, the parser 340, the code generator 350, and the hardware instruction executor 360 to translate standard I/O bus and programmatic commands. The lexical analyzer 330 examines the user-specified standard I/O bus and programmatic commands in both interactive and non-interactive modes. The lexical analyzer 330 generates discrete lexical units called tokens from the standard I/O bus and programmatic commands.

The parser 340 contains grammar rules specifying syntactically and contextually correct grammar for the hardware access language. The parser 340 takes a sequence of tokens produced by the lexical analyzer 330 and compares the sequence of tokens with the grammar to find a match. After the parser 340 finds the match, information regarding the match is stored so that the code generator 350 can later generate intermediate instructions. The code generator 350 generates intermediate instructions in a form ready to be used by the hardware instruction executor 360. If no match is found, an error may be reported to the user.

The intermediate instructions have a one-to-one relationship with low-level (execution) instructions. In various embodiments, intermediate instructions are coded 32-bit instructions that represent pseudo-codes that are portable. The intermediate instructions are decoded and executed by the hardware instruction executor 360. The hardware instruction executor 360 decodes the intermediate instruction one at a time and executes the intermediate instruction as the intermediate instruction is decoded.

In various embodiments, if the intermediate instruction is of a type that can be executed directly by the processor, the hardware instruction executor 360 has the processor execute the intermediate instruction. The hardware instruction executor 360 dispatches the results to other parts of the scripting engine 270, i.e., the graphical user interface module 280. The hardware instruction executor 360 executes the intermediate instruction/low-level instruction in a non-privileged mode. If the intermediate instruction is of a type that uses an I/O bus execution cycle, the hardware instruction executor 360 communicates with the hardware abstraction driver 250 to execute the intermediate instruction as a low-level instruction one I/O bus execution cycle at a time. The hardware abstraction driver 250 executes the low-level instruction in privileged/kernel mode. Having some low-level commands execute in the privileged mode and other low-level commands execute in the non-privileged mode reduces performance due to time delays caused by transitioning between privileged and non-privileged modes.

In other embodiments, the hardware instruction executor 360 decodes and executes in the hardware abstraction driver 250. When hardware instruction executor 360 decodes and executes in the hardware abstraction driver 250, the scripting engine 270 sends blocks of intermediate instructions to the hardware abstraction driver 250. The hardware instruction executor 360 decodes and executes multiple intermediate instructions entirely in privileged/kernel mode. The hardware instruction executor 360 executes direct processor executable instructions, sends results back to the scripting engine 270, and also communicates with other parts of the hardware abstraction driver 250 for I/O bus execution cycles. Thus, the low-level instructions that would otherwise be executed in the non-privileged mode are executed in the privileged mode, thereby enhancing performance by alleviating delays due to switching between the privileged and non-privileged modes.

In various embodiments, the intermediate instructions are similar to low-level instructions because they can be executed individually by the hardware access tool 110, but not by a processor directly. In other embodiments, intermediate instructions are “intermediate” for they are decoded prior to being executed and also, they are not in the form that a processor can use natively. Since intermediate instructions are coded in a non-processor/non-platform coded manner, intermediate instruction may be used independent of host operating systems. Thus, intermediate instruction coding is portable and may be used with a plethora of applications and/or environments.

The set of low-level instructions is a set of execution cycles that can be executed on an I/O device. In some embodiments, a low-level instruction is one execution cycle. In other embodiments, the execution cycle is the sequence of actions that a processor performs to execute each machine code instruction, whereas the low-level instruction is the directive relayed to the I/O device.

In an interactive mode, the hardware instruction executor 360 processes the intermediate instructions one at a time after the user-specified standard I/O bus and programmatic commands are translated. In a non-interactive mode, the intermediate instructions are stored in system memory 160. Later when code branching is requested in the interactive mode, the hardware instruction executor 360 executes the stored intermediate instructions. Non-interactive mode is useful when user commands are grouped together for a common higher-level function to be called in the interactive mode, in interrupt servicing, or in any other delayed processing.

In various embodiments, the hardware access engine 240 provides a universal software driver for any device coupled to the standard I/O bus 170 or a bus bridge device coupled to the standard I/O bus 170. The universal software driver obviates the need for a custom software driver for each device in a computer system.

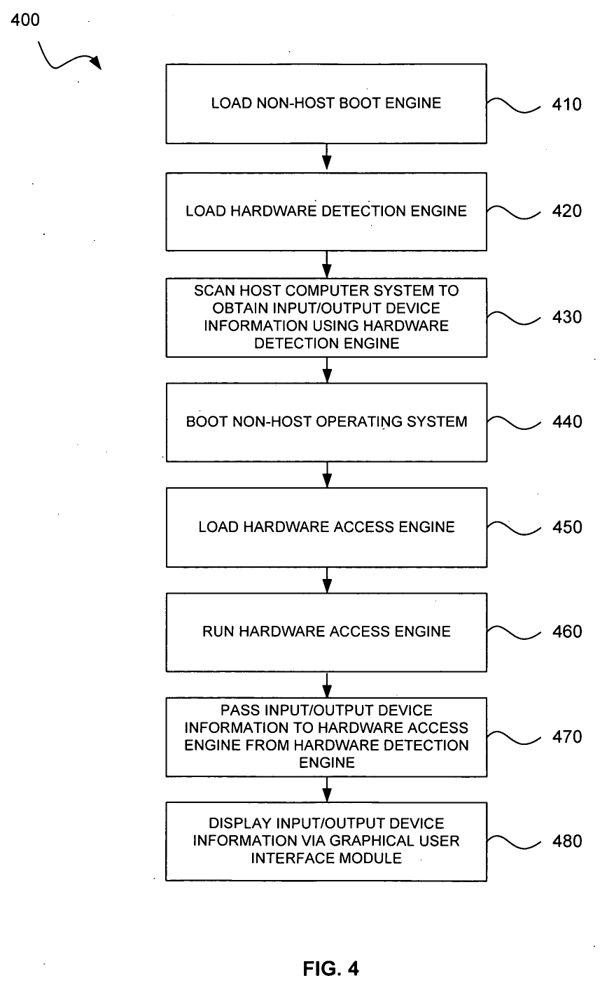

FIG. 4 illustrates a method 400 of starting the hardware access tool 110, according to various embodiments of the invention. Prior to starting the hardware access tool 110, a user directs the host computer system 120 to select the medium that contains the hardware access tool 110 as the primary boot device. In step 410, the non-host boot engine 210 is loaded into the system memory 160. The non-host boot engine 210 directs the startup of the rest of the hardware access tool 110.

In step 420, the hardware detection engine 220 is loaded. In step 430, the hardware detection engine 220 scans the host computer system 120 to identify and obtain information about I/O devices.

After the hardware detection engine 220 has identified hardware components, in step 440, the non-host operating system is booted. Non-host operating system components are loaded into system memory. Also, software to control the I/O devices is loaded into system memory. In various embodiments, the unused binary code portion of the non-host operating system is removed from the system memory 160.

In step 450, the hardware access engine 240 is loaded. In step 460, the hardware access engine 240 runs. Running the hardware access engine 240 starts several applications including the hardware abstraction driver 250, the hardware bus device enumerator 260, the scripting engine 270, and the graphical user interface module 280.

In step 470, the hardware detection engine 220 passes I/O device information to the hardware access engine 240. The hardware bus device enumerator 260 also obtains I/O device configuration and other information based on the execution cycles of the hardware detection engine 220.

In step 480, the graphical user interface module 280 displays I/O device information to a user.

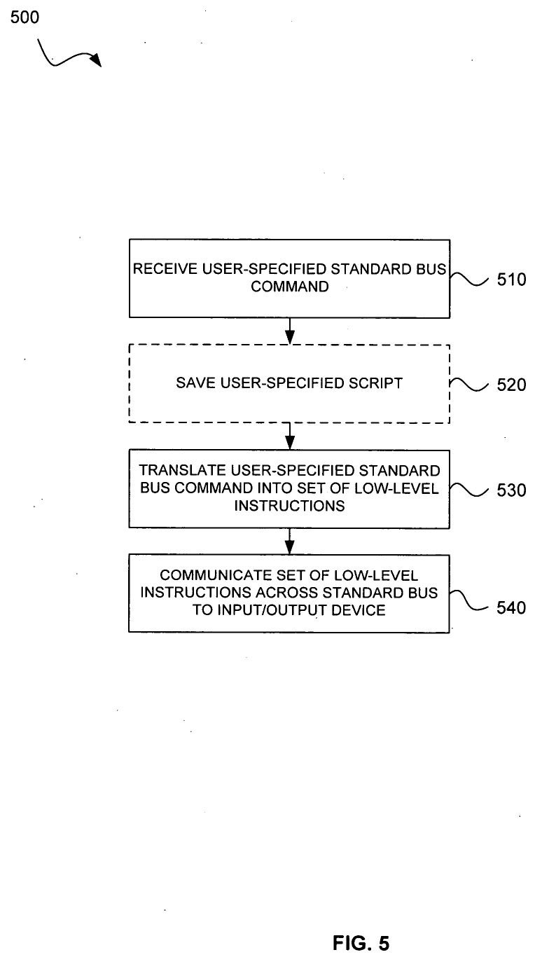

FIG. 5 illustrates a method of using the hardware access tool 110, according to various embodiments of the invention. After the hardware access engine 240 is running, in step 510 the hardware access engine 240 receives a user-specified standard I/O bus command. In some embodiments, the hardware access engine 240 may receive user-specified standard I/O bus commands and/or user-specified programmatic commands. In various embodiments, the user may enter the commands via the graphical user interface module 280.

In step 520, a script is, optionally, saved via the scripting compiler 320. In various embodiments, the scripting compiler 320 allows sequences of user-specified standard I/O bus commands and user-specified programmatic commands to be grouped together and saved as a script. In some embodiments, the scripting compiler 320 saves the intermediate instructions as a script. In some embodiments, the scripting compiler 320 saves the set of low-level instructions as a script. The saved script can then be translated and/or executed either interactively or non-interactively.

In step 530, the scripting engine 270 translates the user-specified standard I/O bus command into a set of low-level instructions. In some embodiments; the hardware access engine 240 translates user-specified standard I/O bus commands and/or user-specified programmatic commands into a set of low-level instructions.

In step 540, the set of low-level instructions is communicated across the standard I/O bus 170 to the I/O device. In some embodiments, the hardware instruction executor 360 has the processor 140 execute each instruction from the set of the low-level instructions. In other embodiments, the hardware instruction executor 360 communicates with the hardware abstraction driver 250 to execute the low-level instruction one at a time. In various embodiments, the hardware instructions executor 360 has the processor 140 execute some low-level instructions and the hardware abstraction driver 250 execute other low-level instructions.

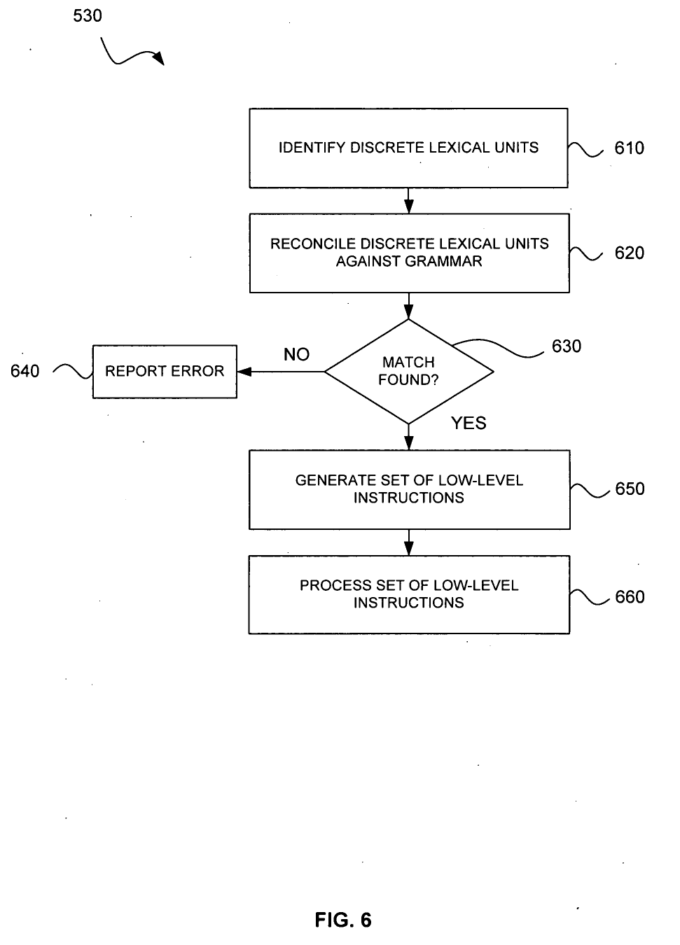

FIG. 6 illustrates a method of translating the user-specified standard I/O bus command into the set of low-level instructions of FIG. 5, step 530, according to various embodiments of the invention. Also, programmatic commands are translated into a set of low-level instructions using the method illustrated in FIG. 6. After the scripting engine 270 receives the user-specified standard I/O bus command, in step 610, the lexical analyzer 330 examines the user-specified standard I/O bus command in both interactive and non-interactive modes and decomposes the user-specified standard I/O bus command into discrete lexical units called tokens.

In step 620, the parser 340 takes a sequence of tokens produced by lexical analyzer 330 and reconciles them against the grammar. In step 630, the parser 340 takes a sequence of tokens produced by the lexical analyzer 330 and compares the sequence of tokens with the grammar to find a match. After the parser 340 finds the match, information regarding the match is stored so that the code generator 350 can later generate intermediate instructions.

If a match is found, then in step 650, the code generator 350 generates intermediate instructions into a form ready to be used by hardware instruction executor 360. If no match is found, then in step 640, an error reported to the user.

In step 660, the hardware instruction executor 360 processes the intermediate instructions. If the hardware instruction executor 360 is in interactive mode, the intermediate instructions are processed as the intermediate instructions are received. If the hardware instruction executor 360 is in a non-interactive mode, the intermediate instructions are stored in system memory 160. The hardware instruction executor 360 later executes the stored intermediate instructions when code branching is requested in the interactive mode.

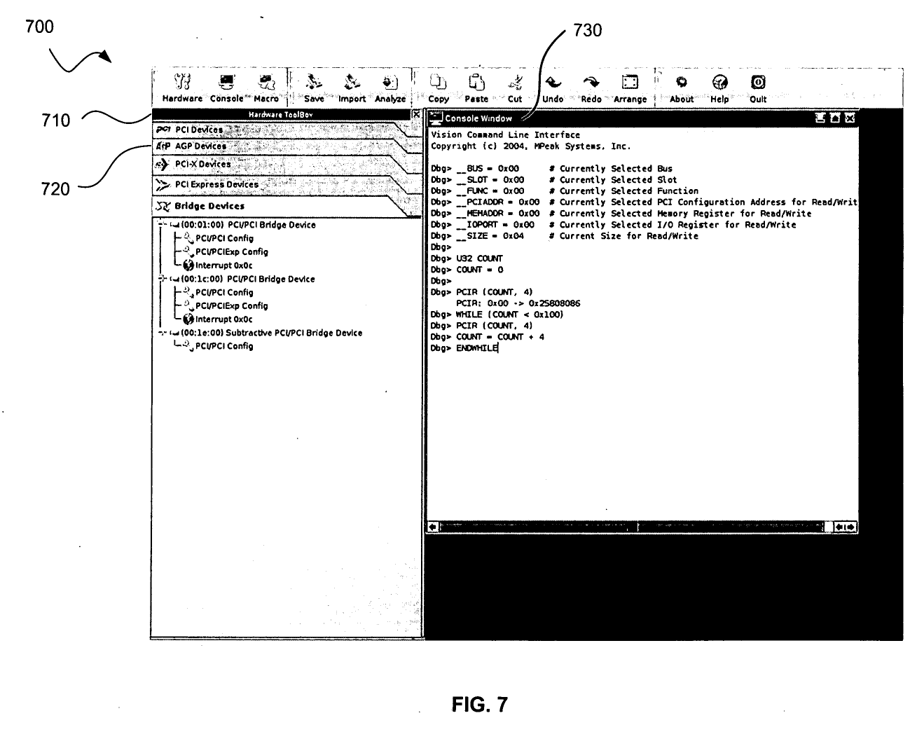

FIG. 7 illustrates a screenshot 700 of a graphical user interface module 280 generating a hardware toolbox 710 and a console window 730, according to various embodiments. The hardware bus device enumerator 260 may generate the hardware toolbox 710. In various embodiments, the hardware toolbox 710 lists the I/O devices attached to a particular bus, as shown, for a PCI family of buses, such as AGP devices 720. The console window 730 allows the user to engage in an interactive session with the I/O device via user-specified commands.

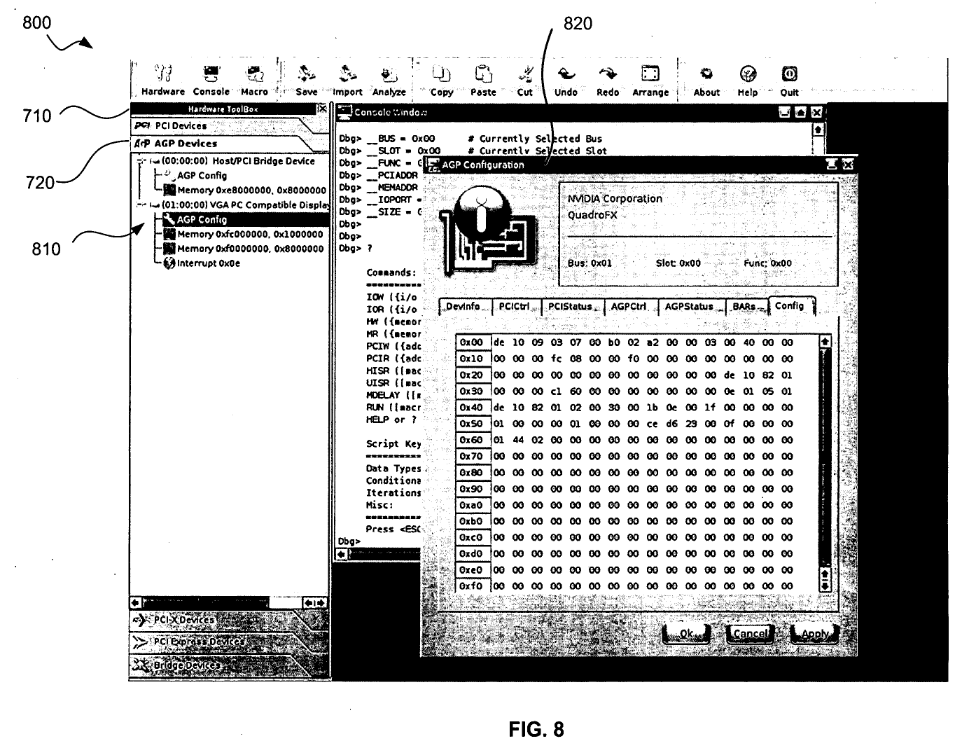

FIG. 8 illustrates a screenshot 800 of a graphical user interface module 280 generating a register configuration of an I/O device, according to various embodiments. In various embodiments, the hardware toolbox 710 shows information about the I/O device when selected. In this screenshot 800, a tab labeled AGP devices 720 is selected, via point-and-click. The hardware toolbox 710 displays a list of I/O devices that are AGP devices. After AGP config 810 is selected, the hardware bus device enumerator 260 provides information to the graphical user interface module 280 to display an AGP configuration 820. In various embodiments, the graphical user interface module 280 displays information of the selected I/O device pertaining to configuration, memory, and interrupt cycles. In some embodiments, the graphical user interface module 280 displays memory reads and writes for both I/O mapped and memory mapped regions. In various embodiments, the I/O mapped and memory mapped regions permit users to access and control status registers and memory buffers.

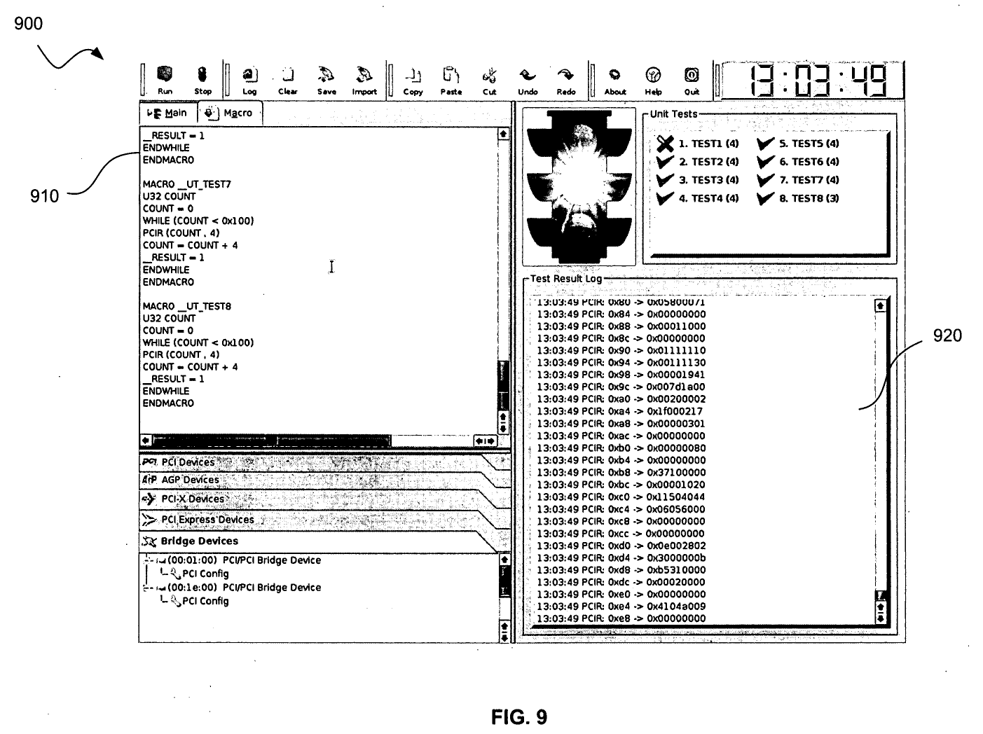

FIG. 9 illustrates a screenshot 900 of a graphical user interface module 280 displaying a script and the test output, according to various embodiments. The script window 910 allows user-specified commands to be entered and saved in the non-interactive mode. The saved scripts are called when in the interactive mode to execute. The saved scripts can be used in other applications, such as a debugging tool used during development of a device under test, a manufacturing tool used during production, or a function call to provide high level application software access to the I/O device without a custom device driver during deployment.

The hardware access tool 110 may be software, firmware or hardware. In various embodiments, the hardware access tool 110 may be written on a bootable compact disc. The compact disc may have a customized Knoppix LiveCD that includes a generic kernel level PCI driver representing the hardware abstraction driver 250, the scripting engine 270, and an application providing the hardware bus device enumerator 260 and the graphical user interface module 280. Such a system may be used as an accessing, configuration, programming, debugging, and testing tool used during development and manufacturing of PCI-based devices without the use of custom software.

In various embodiments, prior to starting the hardware access tool 110 located on a mass storage device, the user would direct the BIOS to look for an operating system on the mass storage device on which the hardware access tool 110 is located. In other embodiments, the hardware access tool 110 may be self-booting, restarting a computer system and directing the BIOS to run the hardware access tool 110. The hardware access tool 110 may be located on any bootable media in a host computer system, such as USB flash media.

In some embodiments, the hardware access tool 110 may provide for remote I/O device accessing. Remote access may be performed over a local network, an intranet, or an Internet. In various embodiments, a user may remotely access an I/O device on a computer system running the hardware access tool 110. In other embodiments, a user running the hardware access tool 110 on a local machine may remotely access an I/O device on a computer system.

The hardware access tool 110 has many benefits. As the hardware access tool 110 is self-contained, it does not require hardware other than the host computer system 120 to operate. The user-specified commands may be entered as standard I/O bus commands, thus reducing time for users to learn additional commands and/or low-level commands. Additionally, the hardware access tool 110 may be used with a wide range of I/O devices, as translation occurs from a user-specified high-level language.

The above-described functions, components, modules, engines and systems can be comprised of instructions that are stored on a storage medium and/or may be implemented as hardware modules. The instructions can be retrieved and executed by a processor. Some examples of instructions are software, program code, and firmware. Some examples of storage medium are memory devices, tape, disks, integrated circuits, and servers. The instructions are operational when executed by the processor to direct the processor to operate in accord with embodiments of the present invention. Those skilled in the art are familiar with instructions, processor(s), and storage medium.

While various embodiments have been described above, it should be understood that they have been presented by way of example only, and not limitation. For example, any of the elements associated with the hardware access tool 110 may employ any of the desired functionality set forth hereinabove. Thus, the breadth and scope of a preferred embodiment should not be limited by any of the above-described exemplary embodiments.

What is claimed is:

1. A method for accessing an input/output device comprising:
running a non-host operating system on a host computer system, the non-host operating system being separate from a host operating system;
receiving a first user-specified standard input/output bus command;
translating the first user-specified standard input/output bus command into a first set of low-level instructions; and
communicating the first set of low-level instructions across a standard input/output bus to the input/output device for execution.

2. The method of claim 1, wherein the step of receiving the first user-specified standard input/output bus command comprises receiving a second user-specified standard input/output bus command and a user-specified programmatic command, and comprises saving the first user-specified standard input/output bus command, the second user-specified standard input/output bus command, and the user-specified programmatic command as a script.

3. The method of claim 2, further comprising translating the script into a second set of low-level instructions and saving the second set of low-level instructions.

4. The method of claim 3, further comprising using the script as a function call.

5. The method of claim 2, further comprising translating the script into a third set of low-level instructions and communicating the third set of low-level instructions across the standard input/output bus to the input/output device for execution.

6. The method of claim 5, further comprising configuring the input/output device using the third set of low-level instructions.

7. The method of claim 5, further comprising executing the third set of low-level instructions in a privileged mode.

8. The method of claim 1, further comprising determining functionality of the input/output device.

9. The method of claim 1, further comprising determining configuration of the input/output device.

10. The method of claim 1, further comprising configuring the input/output device using the first set of low-level instructions.

11. The method of claim 1, further comprising reading and writing to the input/output device's memory using the first set of low-level instructions.

12. The method of claim 1, wherein the first set of low-level instructions are isochronous read and write cycles.

13. The method of claim 1, wherein the first set of low-level instructions are asynchronous read and write cycles.

14. The method of claim 1, wherein the first set of low-level instructions are bulk read and write cycles.

15. The method of claim 1, further comprising scanning the host computer system to determine input/output devices connected to the standard input/output bus.

16. The method of claim 1, further comprising receiving a user-selection of the input/output device from a list of input/output devices connected to the host computer system via the standard input/output bus.

17. The method of claim 1, wherein the step of receiving the first user-specified standard input/output bus command is performed via a graphical user interface module.

18. The method of claim 1, further comprising depicting graphically portions of the input/output device.

19. The method of claim 1, further comprising booting the non-host operating system from a non-host boot engine, the non-host boot engine being different from the host computer system's boot device.

20. A computer readable medium having embodied thereon a program, the program being executable by a processor for performing a method for accessing an input/output device, the method comprising the steps of:
running a non-host operating system on a host computer system, the non-host operating system being separate from a host operating system;
receiving a user-specified standard input/output bus command;
translating the first user-specified standard input/output bus command into a first set of low-level instructions; and
communicating the first set of low-level instructions across a standard input/output bus to the input/output device for execution.

21. The computer readable medium of claim 20, wherein the program being executable by the processor for performing the method further comprises the step of booting the non-host operating system from a non-host boot engine, the non-host boot engine being different from the host computer system's boot device.

22. The computer readable medium of claim 20, wherein the step of receiving the first user-specified standard input/output bus command further comprises receiving a second user-specified standard input/output bus command and a user-specified programmatic command and saving the first user-specified standard input/output bus command, the second user-specified standard input/output bus command, and the user-specified programmatic command as a script.

23. The computer readable medium of claim 22, wherein the program being executable by the processor for performing the method further comprises the step of translating the script into a second set of low-level instructions and communicating the second set of low-level instructions across the standard input/output bus to the input/output device for execution.

24. The computer readable medium of claim 20, wherein the program being executable by the processor for performing the method further comprises the step of configuring the input/output device using the first set of low-level instructions.

25. A system for accessing an input/output device comprising:
a host computer system configured to run a non-host operating system, the non-host operating system being separate from a host operating system; and
a hardware access tool configured to receive a user-specified standard input/output bus command, to translate the first user-specified standard input/output bus command into a first set of low-level instructions, and to communicate the first set of low-level instructions across a standard input/output bus to the input/output device for execution.

26. The system of claim 25, further comprising a non-host boot engine configured to boot the non-host operating system on the host computer system.

27. The system of claim 25, further comprising a scripting compiler configured to save the first user-specified standard input/output bus command and one or more user-specified programmatic commands.

28. The system of claim 27, wherein translating the script into a second set of low-level instructions and communicating the second set of low-level instructions across the standard input/output bus to the input/output device for execution.

29. The system of claim 25, further comprising a hardware access engine configured to operate as a universal software driver for any device coupled to the standard input/output bus.

30. The system of claim 25, wherein the hardware access tool is further configured to provide for remote input/output device accessing.
